(19) United States
(12) Patent Application Publication
(10) Pub. No.: US 2026/0267604 A1
(43) Pub. Date: Sep. 10, 2026

(54) CROSSING FREQUENCY AND POWER DOMAINS

(71) Applicant: Google LLC, Mountain View, CA (US)

(72) Inventors: David Samuel Warren, Campbell, CA (US); Parimal Gaikwad, Sunnyvale, CA (US)

(21) Appl. No.: 19/164,960

(22) PCT Filed: Mar. 20, 2023
(86) PCT No.: PCT/US2023/015653

§ 371 Date: Sep. 12, 2025

(51) Int. Cl. G06F 5/06; H03K 19/0175

(52) U.S. Cl. CPC G06F 5/065; H03K 19/017509

(57) ABSTRACT

An asynchronous FIFO system (300) for transferring data from a sending power domain (302) to a receiving power domain (304) on a chip includes a plurality of storage elements (308) and a plurality of cycling multiplexors (310, 312) in the sending power domain, a data toggling multiplexor (318) and a plurality of pointer generators (314, 316) in the receiving power domain, and a plurality of level shifters (322a-d) arranged between the cycling multiplexors in the sending power domain (302) and other elements in the receiving power domain, wherein each pointer generator is configured to feed a respective pointer value to a respective cycling multiplexor to cause each cycling multiplexor to forward nonconsecutive data (1, 3, 5, 7 or 0, 2, 4, 6) from the plurality of storage elements (308), and wherein the data toggling multiplexor (318) is configured to read from the plurality of cycling multiplexors (310, 312) in a cycle to reconstruct data (0, 1, 2, 3, 4, 5, 6, 7, 8) in the plurality of storage elements in the receiving power domain.

### BACKGROUND

In modern computer chip designs, different components of the chip can run at different voltages and different frequencies. For example, components that have a lower performance can run at a lower voltage, e.g., to save power or to reduce device temperature. Components that run at similar frequencies/voltages can be grouped into frequency domains and power domains. Crossing data between frequency domains and power domains can require a large number of level shifters, which are circuits used to translate signals from one logic level or voltage domain to another, which in turn require a large amount of silicon area and can cause issues in designing the chip.

### SUMMARY

This specification describes methods and systems to reduce the number of level shifters required to cross frequency and power domains while retaining latency in the design, e.g., in an asynchronous first in first out (FIFO) design. For example, crossing frequency and power domains can often require a large number of level shifters. The present methods and systems can reduce the number of level shifters and maintain a desired latency. For example, a number of cycling multiplexors can alternate reading data and sending the data through level shifters. The increased number of multiplexors can increase the amount of data that is crossing the frequency and power domains without significantly increasing the number of level shifters.

Particular embodiments of the subject matter described in this specification can be implemented so as to realize one or more of the following advantages.

The described methods and systems improve the design of computer chips by reducing the number of level shifters required to cross frequency and power domains, which in turn reduces the amount of area that is required for crossing frequency and power domains. The described methods and systems can also allow single cycle latency while reducing the number of level shifters.

The details of one or more embodiments of the subject matter of this specification are set forth in the accompanying drawings and the description below. Other features, aspects, and advantages of the subject matter will become apparent from the description, the drawings, and the claims.

### BRIEF DESCRIPTION OF THE DRAWINGS

FIG. 1 is a diagram of an example chip design.

FIG. 2 is a diagram of an example chip design with a reduced number of level shifters relative to the design of FIG. 1.

FIG. 3 is a diagram of an example chip design with a reduced number of levels shifters relative to the design of FIG. 1 while retaining single cycle latency.

Like reference numbers and designations in the various drawings indicate like elements.

### DETAILED DESCRIPTION

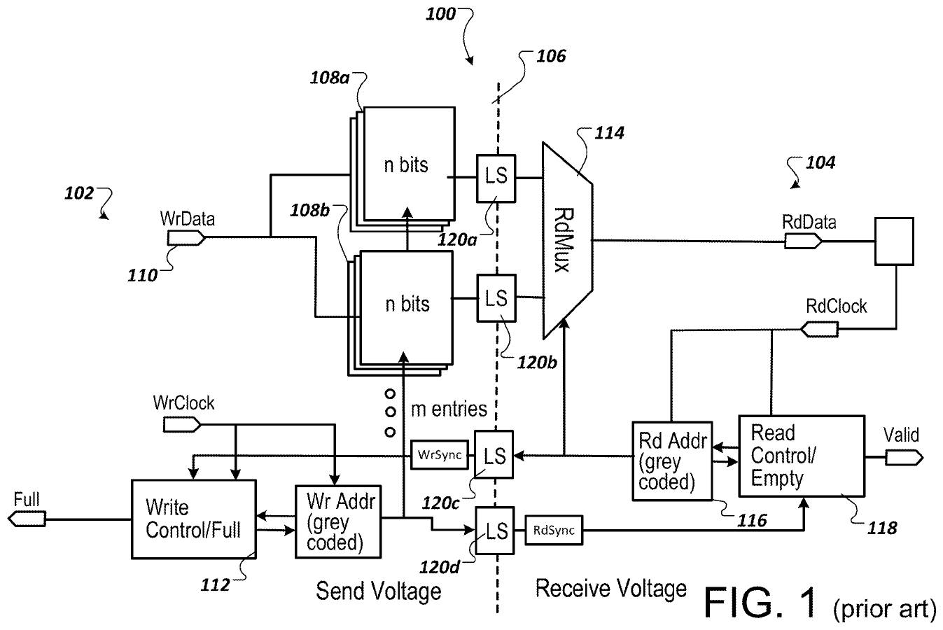

FIG. 1 is a diagram of an example prior art level-crossing chip design 100. The chip design 100 is an example of a chip design that can be included in any appropriate stationary or mobile computing device, e.g., a computing chip in a mobile phone, a tablet computer, a laptop computer, or a desktop computer, to name just a few examples.

The chip design 100 includes a sending power domain 102 and a receiving power domain 104. For example, the sending power domain 102 can operate at a different voltage, e.g., a higher voltage or lower voltage, than the receiving power domain 104. The sending power domain 102 and receiving power domain 104 are separated by a power domain boundary 106, depicted as a dashed line 106 for illustration. The sending power domain 102 includes first-in, first-out (FIFO) queues 108 implemented by a plurality of storage elements for sending data over the power domain boundary 106.

Incoming data 110 can be stored in the FIFOs 108. The FIFOs can be implemented by any appropriate storage logic, e.g., registers or random-access memories. A write logic circuit 112 processes incoming clock signals in the sending power domain 102 to control how quickly the sending power domain 102 operates. The receiving power domain 104 includes a data toggling multiplexor 114 to toggle from which storages 108 the multiplexor 114 reads. The receiving power domain 104 also includes pointer generators 116 that feed pointer values to the multiplexor 114 to cause the multiplexor 114 to forward data from the storages 108. A read logic circuit 118 processes incoming clock signals in the reading power domain 104, e.g., to control how quickly the reading power domain 104 operates.

A number of level shifters 120a-d are arranged between the sending power domain 102 and the receiving power domain 104. The level shifters 120a-d can include circuits used to translate signals from one logic level or voltage domain to another. The level shifters 120a-d can translate signals, e.g., from the sending power domain 102 to the reading power domain 104 or from the reading power domain 104 to the sending power domain 102. Level shifters are required when a signal is sent from one of the domains 102, 104 to the other domain 102, 104.

The chip design 100 illustrated in FIG. 1 can require an unacceptably large number of level shifters. In an example with m storage elements in the FIFOs 108, wherein each storage element contains n bits, the chip design 100 requires m*n level shifters 120 to send signals from the sending power domain 102 to the receiving power domain 104, and vice versa. As the desired amount of storage grows, the required number of level shifters 120 grows quadratically. In turn, as the required number of level shifters 120 grows, the amount of area required for shifting levels increases.

Alternative designs can reduce the large number of level shifters to increase the amount of area available for other components.

Depending on the arrangement of the level shifters 120 and the design of the chip, the number of required level shifters can be reduced, e.g., to reduce the amount of area that is required for these components. Reducing the amount of area required for the level shifters 120 can provide additional area for other components.

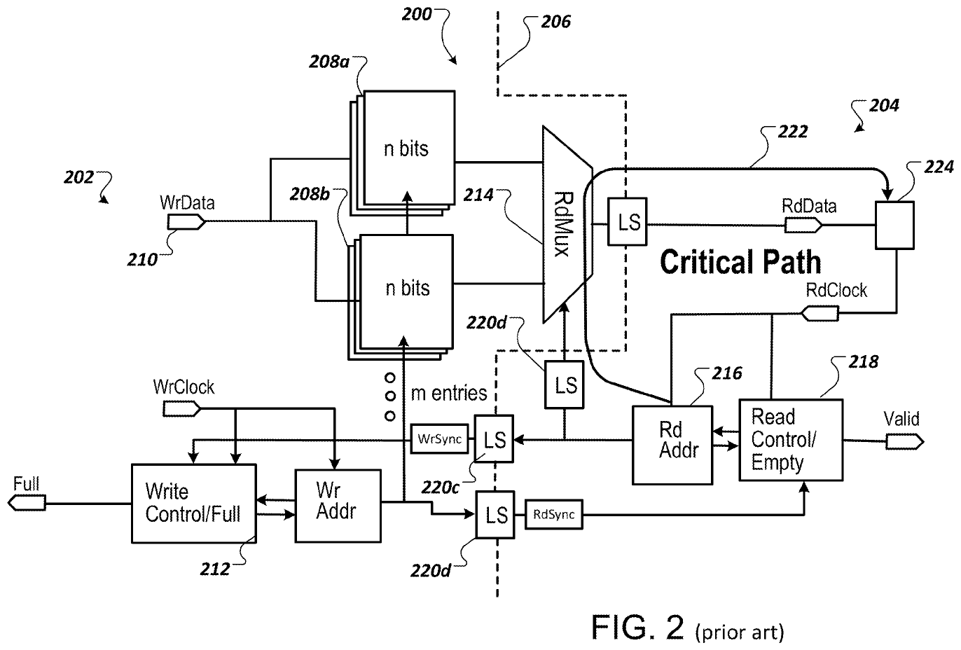

FIG. 2 illustrates an example prior art level-crossing chip design 200 that requires fewer level shifters than the chip design 100 illustrated in FIG. 1. The chip design 100 is an example of a chip design that can be included in any appropriate stationary or mobile computing device, e.g., a computing chip in a mobile phone, a tablet computer, a laptop computer, or a desktop computer, to name just a few examples. The chip design 200 includes a sending power domain 202 and a receiving power domain 204. For example, the sending power domain 202 can operate at a different voltage, e.g., a higher voltage or lower voltage, than the receiving power domain 204. The sending power domain 202 and receiving power domain 204 are separated by a power domain boundary 206, depicted as a dashed line 206 for illustration. The sending power domain 202 includes FIFO queues 208a, 208b implemented by a plurality of storage elements for sending data over the power domain boundary 206. Incoming data 210 can be stored in the FIFOs 208a, 208b. The FIFOs can be implemented by any appropriate storage logic, e.g., registers or random-access memories. A write logic circuit 212 processes incoming clock signals in the sending power domain 202 to control how quickly the sending power domain 202 operates. The sending power domain 202 further includes a data toggling multiplexor 214 to toggle between which storages 208a, 208b the multiplexor 214 reads. Placing the data toggling multiplexor 214 in the sending power domain 202 can reduce the number of required level shifters, as discussed further below. The receiving power domain 204 includes pointer generators 216 that feed pointer values to the multiplexor 214 to cause the multiplexor 214 to forward data from the storages 208a, 208b. A read logic circuit 218 processes incoming clock signals in the reading power domain 204, e.g., to control how quickly the reading power domain 204 operates.

A number of level shifters 220a, 220b, 220c, 220d are arranged between the sending power domain 102 and the receiving power domain 204. The number of required level shifters can be reduced relative to the chip design 100 of FIG. 1, e.g., to reduce the amount of area required, as described above. The chip design 200 illustrated in FIG. 2 requires far fewer level shifters than the chip design 100 illustrated in FIG. 1. By moving the level shifters 220 around the multiplexor 214, e.g., by moving the multiplexor into the sending power domain 202, the required number of level shifters 220 can be significantly reduced. In an example with m storage elements 208, wherein each storage contains n bits, the chip design 200 requires n+log(m) level shifters 220 to send signals from the sending power domain 202 to the receiving power domain 204, and vice versa. As the desired amount of storage grows, the required number of level shifters 220 grows at a much lower rate than chip design 100, which required n*m level shifters. Also, because the required number of level shifters 220 grows at a much lower rate than that of the chip design 100, the amount of area required for shifting levels increases at a much lower rate than that of the chip design 100.

The chip design 200 illustrated in FIG. 2 requires far fewer level shifters than the chip design 100 of FIG. 1, but reducing the number of level shifters can create other issues, e.g., timing issues, latency issues, etc. One example of an issue in the chip design 200 of FIG. 2 is a timing issue created when the voltage of the sending power domain 202 is low and the timing of the read clock is fast, e.g., the reading power domain 204 operates quickly. For example, a critical timing path 222 is illustrated in which a signal must travel from the pointer generators 216, through a level shifter 220, through the multiplexor 214, and through a second level shifter 220 as output data 224. The critical timing path 222 is a long timing path for a signal to travel through and can create timing issues. For example, the timing delay caused by a level shifter increases approximately proportionally with the voltage difference between the sending power domain 202 and the receiving power domain 204. When the voltage of the sending power domain 202 is low and the timing of the read clock is fast, which means that the receiving voltage will be high, the timing delay caused by the level shifter 220 will be large. Additionally, the signal passing through the critical timing path 222 passes through two level shifters, so the timing delay is even greater.

Another example of an issue in the chip design 200 of FIG. 2 is a latency issue. For example, a fast read clock may not be desirable because it can create timing issues, as described above. However, a slow read clock creates latency in the design, reducing the bandwidth significantly. For example, one simple way to solve the timing issue described above is to read data from the multiplexor 214 on alternating cycles, e.g., every other cycle. However, reading data from the multiplexor 214 on alternating cycles requires twice the number of read clock cycles to read the data from the storages 208 than the number of cycles required to read the data from the storages in the chip design 100 of FIG. 1. While the chip design 200 of FIG. 2 can be favorable and reduces the number of level shifters relative to the chip design 100 of FIG. 1, the chip design 200 of FIG. 2 also presents additional issues, e.g., timing issues and latency issues, as discussed above. However, alternative designs can reduce the large number of level shifters to increase the amount of area available for other components.

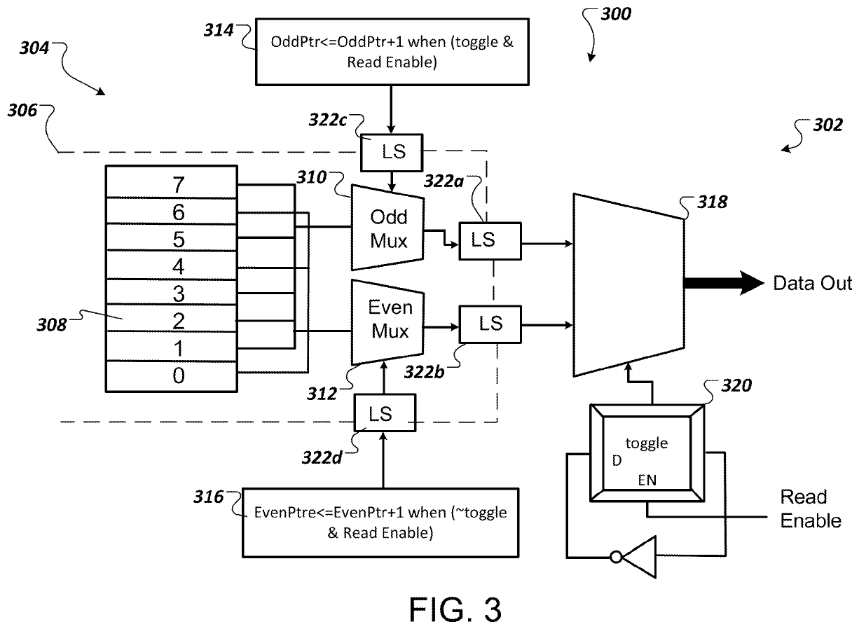

FIG. 3 illustrates a chip design 300 that requires fewer level shifters than the chip design 100 illustrated in FIG. 1. The chip design 300 includes a sending power domain 302 and a receiving power domain 304. For example, the sending power domain 302 can operate at a different voltage, e.g., a higher voltage or lower voltage, than the receiving power domain 304. The sending power domain 302 and receiving power domain 304 are separated by a power domain boundary 306, depicted as a dashed line 306 for illustration. The sending power domain 302 includes a FIFO queue 308 implemented by a storage element for sending data over the power domain boundary 306. Incoming data can be stored in the FIFO 308. In the illustrated example, the storage 308 is a register. A write logic circuit can process incoming clock signals in the sending power domain 302 to control how quickly the sending power domain 302 operates. The write logic circuit can be similar to the write logic circuits of FIGS. 1 and 2. The sending power domain 302 further includes two cycling multiplexors 310, 312 to toggle between nonconsecutive data in the FIFO 308. For example, since there are two cycling multiplexors 310, 312, they can alternate reading the data in the FIFO 308, such that one multiplexor is an odd multiplexor, e.g., reading in data from the first, third, fifth address, etc., and the other multiplexor is an even multiplexor, e.g., reading in data from the second, fourth, sixth, etc. address.

In some implementations, there are more storages and there are more cycling multiplexors, e.g., three multiplexors, four multiplexors, etc. In implementations with more cycling multiplexors, the multiplexors split the data in the register according to the number of multiplexors. For example, in an implementation with three cycling multiplexors, the multiplexors would read in every third address, e.g., the first multiplexor would read in the first, fourth, seventh, etc. address, the second multiplexor would read in the second, fifth, eighth, etc. address, and the third multiplexor would read in the third, sixth, ninth, etc. address. Splitting the data according to the number of multiplexors can be done for any number of multiplexors. The number of addresses does not need to be divisible by the number of multiplexors. As illustrated, the first cycling multiplexor 310 receives pointers from a pointer generator 314 that instruct the first cycling multiplexor 310 to read from the odd addresses, e.g., the first, third, fifth, etc. address. The second cycling multiplexor 312 receives pointers from a pointer generator 316 that instructs the second cycling multiplexor 312 to read from the even addresses, e.g., the second, fourth, sixth, etc. address. Using cycling multiplexors can remove latency issues, e.g., similar to those described with respect to FIG. 2.

The chip design 300 also includes a data toggling multiplexor 318 in the receiving power domain 304. The data toggling multiplexor 318 receives pointers from the pointer generator 320 that instruct the data toggling multiplexor 318 to alternate reading data from the first cycling multiplexor 310 and the second cycling multiplexor 312. Using the data toggling multiplexor 318 to alternate reading data from the first cycling multiplexor 310 and the second cycling multiplexor 312 can reduce or remove the timing issues presented in the chip design 200 of FIG. 2, as discussed further below. The receiving power domain 304 includes a toggle 320 that toggles the multiplexor 318 to alternate reading data from the first cycling multiplexor 310 and the second cycling multiplexor 312. The receiving power domain can also include a read logic circuit that processes incoming clock signals in the reading power domain 304, e.g., to control how quickly the reading power domain 304 operates. For example, the read logic circuit can be similar to the read logic circuits of FIGS. 1 and 2.

A number of level shifters 322a, 322b, 322c, 322d are arranged between the sending power domain 302 and the receiving power domain 304. For example, level shifters 322a, 322b are arranged between the cycling multiplexors 310, 312 and the data toggling multiplexor 318. The chip design 300 illustrated in FIG. 3 requires fewer level shifters than the chip design 100 illustrated in FIG. 1, and the chip design 300 illustrated in FIG. 3 does not have the timing and latency issues presented in FIG. 2.

In an example with m storages 308, wherein each storage contains n bits, the chip design 300 requires 2(n+log(m)) level shifters to send signals from the sending power domain 302 to the receiving power domain 304, and vice versa. As the desired amount of storage grows, the required number of level shifters grows at a lower rate than chip design 100, which required n*m level shifters. Also, because the required number of level shifters grows at a much lower rate than that of the chip design 100, the amount of area required for shifting levels increases at a much lower rate than that of the chip design 100.

The chip design 300 can also reduce or remove the issues, e.g., timing and latency issues, presented in chip design 200. For example, level shifters 322a, 322b are arranged between the cycling multiplexors 310, 312 and the data toggling multiplexor 318. There is still a timing delay as data passes through one of the level shifters 322a, 322b. However, during the timing delay, the other cycling multiplexor can read data from the storage and send the data into the other level shifter 322a, 322b. When the data toggling multiplexor 318 receives data from one of the level shifters and sends the data forward, data in the other level shifter is ready to be read by the multiplexor 318, e.g., because the cycling multiplexors can continue to send data to the level shifters during timing delays caused by the level shifters. The timing delay is unnoticeable by the end user because while one level shifter is causing a timing delay the other cycling multiplexor is passing data from the storage through the other level shifter. For example, during a first cycle, the data toggling multiplexor 318 can receive a signal from a first level shifter 322a and forward the signal to other components. During the first cycle, the cycling multiplexor 312 can read data from the storage and send the data to the second level shifter 322b, and the second level shifter 322b can process the data, e.g., to translate the signals from the sending power domain 302 to the receiving power domain 304. During a second cycle, the data toggling multiplexor 318 can receive the signal from the second level shifter 322b and forward the signal to other components. During the second cycle, the cycling multiplexor 310 can read data from the storage and send the data to the first level shifter 322a, and the first level shifter 322a can process the data, e.g., to translate the signals from the power domain 302 to the receiving power domain 304. In this fashion, the data toggling multiplexor 318 can receive and forward data every cycle. The cycling of the cycling multiplexors removes the timing and latency issues described with reference to FIG. 2.

Although the chip design 300 of FIG. 3 requires more level shifters than the chip design 200 of FIG. 2, e.g., 2(n+log(m)) instead of n+log(m), the chip design 300 also reduces or removes timing and latency issues presented by the chip design of FIG. 2. The chip design 300 can be desirable over the chip design 200 of FIG. 2 because it reduces the timing and latency issues. The chip design 300 also requires a lower number of level shifters than the chip design 100 of FIG. 1. The chip design 300 can be desirable over the chip design 100 of FIG. 1 because it requires a lower number of level shifters.

Embodiments of the subject matter and the functional operations described in this specification can be implemented in digital electronic circuitry in computer hardware, including the structures disclosed in this specification and their structural equivalents, or in combinations of one or more of them. The processes and logic flows can also be performed by special purpose logic circuitry, e.g., an FPGA or an ASIC, or by a combination of special purpose logic circuitry and one or more programmed computers.

In addition to the embodiments described above, the following embodiments are also innovative:
Embodiment 1 is an asynchronous FIFO system for transferring data from a sending power domain to a receiving power domain on a chip, the asynchronous FIFO system comprising:
a plurality of storage elements and a plurality of cycling multiplexors in the sending power domain;
a data toggling multiplexor and a plurality of pointer generators in the receiving power domain; and
a plurality of level shifters arranged between the cycling multiplexors in the sending power domain and other elements in the receiving power domain,
wherein each pointer generator is configured to feed a respective pointer value to a respective cycling multiplexor to cause each cycling multiplexor to forward nonconsecutive data from the plurality of storage elements, and
wherein the data toggling multiplexor is configured to read from the plurality of cycling multiplexors in a cycle to reconstruct data in the plurality of storage elements in the receiving power domain.
Embodiment 2 is the system of embodiment 1, wherein the cycling multiplexors are divided into even and odd multiplexors.
Embodiment 3 is the system of any one of embodiments 1-2, wherein the cycling multiplexors comprise two multiplexors.
Embodiment 4 is the system of any one of embodiments 1-3, wherein a portion of the plurality of level shifters are arranged between the cycling multiplexors and the data toggling multiplexor.
Embodiment 5 is the system of any one of embodiments 1-4, wherein the plurality of storage elements comprises a plurality of registers.
Embodiment 6 is the system of any one of embodiments 1-5, wherein each of the cycling multiplexors is configured to forward the nonconsecutive data into a respective one of the plurality of level shifters.
Embodiment 7 is a method of transferring data from a sending power domain to a receiving power domain on a chip comprising:
feeding a respective pointer value to a respective cycling multiplexor to cause each cycling multiplexor to forward nonconsecutive data from a plurality of storage elements; and
reading from the plurality of cycling multiplexors in a cycle to reconstruct data in the plurality of storage elements in the receiving power domain.
Embodiment 8 is the method of embodiment 7, wherein the cycling multiplexors are divided into even and odd multiplexors.
Embodiment 9 is the method of any one of embodiments 7-8, wherein the cycling multiplexors comprise two multiplexors.
Embodiment 10 is the method of any one of embodiments 7-9, further comprising arranging level shifters between the cycling multiplexors and a data toggling multiplexor.
Embodiment 11 is the method of any one of embodiments 7-10, wherein the plurality of storage elements comprises a plurality of registers.
Embodiment 12 is the method of any one of embodiments 7-11, wherein each of the cycling multiplexors forwards the nonconsecutive data into one of a plurality of level shifters.

While this specification contains many specific implementation details, these should not be construed as limitations on the scope of any invention or on the scope of what may be claimed, but rather as descriptions of features that may be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In certain cases, multitasking and parallel processing may be advantageous.

What is claimed is:

1. An asynchronous FIFO system for transferring data from a sending power domain to a receiving power domain on a chip, the asynchronous FIFO system comprising:
a plurality of storage elements and a plurality of cycling multiplexors in the sending power domain;
a data toggling multiplexor and a plurality of pointer generators in the receiving power domain; and
a plurality of level shifters arranged between the cycling multiplexors in the sending power domain and other elements in the receiving power domain,
wherein each pointer generator is configured to feed a respective pointer value to a respective cycling multiplexor to cause each cycling multiplexor to forward nonconsecutive data from the plurality of storage elements, and
wherein the data toggling multiplexor is configured to read from the plurality of cycling multiplexors in a cycle to reconstruct data in the plurality of storage elements in the receiving power domain.

2. The system of claim 1, wherein the cycling multiplexors are divided into even and odd multiplexors.

3. The system of claim 1, wherein the cycling multiplexors comprise two multiplexors.

4. The system of claim 1, wherein a portion of the plurality of level shifters are arranged between the cycling multiplexors and the data toggling multiplexor.

5. The system of claim 1, wherein the plurality of storage elements comprises a plurality of registers.

6. The system of claim 1, wherein each of the cycling multiplexors is configured to forward the nonconsecutive data into a respective one of the plurality of level shifters.

7. A method of transferring data from a sending power domain to a receiving power domain on a chip, the method comprising:
feeding a respective pointer value to a respective cycling multiplexor to cause each cycling multiplexor to forward nonconsecutive data from a plurality of storage elements; and
reading from the plurality of cycling multiplexors in a cycle to reconstruct data in the plurality of storage elements in the receiving power domain.

8. The method of claim 7, wherein the cycling multiplexors are divided into even and odd multiplexors.

9. The method of claim 7, wherein the cycling multiplexors comprise two multiplexors.

10. The method of claim 7, further comprising arranging level shifters between the cycling multiplexors and a data toggling multiplexor.

11. The method of claim 7, wherein the plurality of storage elements comprises a plurality of registers.

12. The method of claim 7, wherein each of the cycling multiplexors forwards the nonconsecutive data into one of a plurality of level shifters.
